(19) United States
(12) Patent Application Publication
(10) Pub. No.: US 2026/0188368 A1
(43) Pub. Date: Jul. 2, 2026

(54) MEMORY DEVICE

(71) Applicant: SK hynix Inc., Gyeonggi-do (KR)

(72) Inventor: Chang Hyun KIM, Gyeonggi-do (KR)

(21) Appl. No.: 19/283,241

(22) Filed: Jul. 29, 2025

(30) Foreign Application Priority Data
Dec. 30, 2024 (KR) 10-2024-0200275

(51) Int. Cl. G11C 8/10; G11C 7/10; G11C 8/18

(52) U.S. Cl. CPC G11C 8/10; G11C 7/1069; G11C 7/1096; G11C 8/18

(57) ABSTRACT

Embodiments of the present disclosure relate to a memory device including at least one data line, a normal memory coupled to the data line and configured to output read data to the data line through a normal read operation during a cache load mode; a cache memory coupled to the data line and configured to write the read data as load data through a cache write operation during the cache load mode; and a controller configured to control the normal read operation of the normal memory and the cache write operation of the cache memory by generating and using a self-strobe signal and a self-column address signal during the cache load mode.

### CROSS-REFERENCE TO RELATED APPLICATION(S)

This application claims priority under 35 U.S.C. § 119 to Korean Patent Application No. 10-2024-0200275, filed on Dec. 30, 2024, the disclosure of which is incorporated herein by reference in its entirety.

### BACKGROUND

### 1. Field

Various embodiments of the present disclosure relate to a semiconductor design technique, and more particularly, to a memory device.

### 2. Description of the Related Art

A memory device is broadly categorized into volatile memory devices and non-volatile memory devices.

A volatile memory device is a memory device in which data is stored only when the power supply is supplied and stored data is lost when the power supply is cut off. The volatile memory device may include a static random access memory (SRAM) and a dynamic random access memory (DRAM).

A non-volatile memory device retains stored data even when the power supply is cut off. The non-volatile memory device may include a read only memory (ROM), a programmable ROM (PROM), an electrically programmable ROM (EPROM), an electrically erasable and programmable ROM (EEPROM), and a flash memory.

As the integration of memory devices increases, access time increases during a read operation or a write operation of the memory device.

### SUMMARY

Various embodiments of the present disclosure are directed to a memory device including a cache memory.

In accordance with an embodiment of the present disclosure, a memory device may include a normal memory configured to perform a normal read operation or a normal write operation based on a first command signal, a first column address signal and a row address signal; a cache memory configured to perform a cache read operation or a cache write operation based on a second command signal and a second column address signal; a comparator configured to compare a previous row address signal with a current row address signal and generate a comparison signal corresponding to the comparison result; a handler configured to generate a load control signal, a self-strobe signal, a self-column address signal and the row address signal based on an active signal, a flag signal, the current row address signal and the comparison signal; and a control switch configured to generate the first command signal, the first column address signal, the second command signal and the second column address signal based on the load control signal, the self-strobe signal and the self-column address signal.

In accordance with an embodiment of the present disclosure, a memory device may include at least one data line; a normal memory coupled to the data line and configured to output read data to the data line through a normal read operation during a cache load mode; a cache memory coupled to the data line and configured to write the read data as load data through a cache write operation during the cache load mode; and a controller configured to control the normal read operation of the normal memory and the cache write operation of the cache memory by generating and using a self-strobe signal and a self-column address signal during the cache load mode.

In accordance with an embodiment of the present disclosure, a memory device may include a memory cell array; a cache memory; and
a controller configured to: perform a normal read operation or a normal write operation on the memory cell array based on a first command signal, a first column address signal and a row address signal, perform a cache read operation or a cache write operation on the cache memory based on a second command signal and a second column address signal,
during a cache mode, generate the first command signal and the first column address signal or the second command signal and the second column address signal, and during a precharge mode, generate the second command signal and the second column address signal, and then generate the first command signal and the first column address signal.

### BRIEF DESCRIPTION OF THE DRAWINGS

FIG. 1 is a block diagram illustrating a memory device in accordance with an embodiment of the present disclosure.

FIG. 2 is a block diagram illustrating the controller illustrated in FIG. 1.

FIGS. 3 to 6 are timing diagrams of an operation of the memory device illustrated in FIG. 1.

### DETAILED DESCRIPTION

Various embodiments of the present disclosure are described below with reference to the accompanying drawings, in order to describe in detail the embodiments of the present disclosure so that those with ordinary skill in art to which the present disclosure pertains may easily carry out the technical spirit of the present disclosure.

It will be understood that when an element is described as being “connected to” or “coupled to” another element, the connection may be direct, or it may be indirect through one or more intervening elements, either physically or electrically. In addition, it will also be understood that the terms “comprises,” “comprising,” “includes,” and “including” when used in this specification do not preclude the presence of one or more other elements, but may further include or have the one or more other elements, unless otherwise mentioned. In the description throughout the specification, some components are described in singular forms, but the present disclosure is not limited thereto, and it will be understood that the components may be formed in plural.

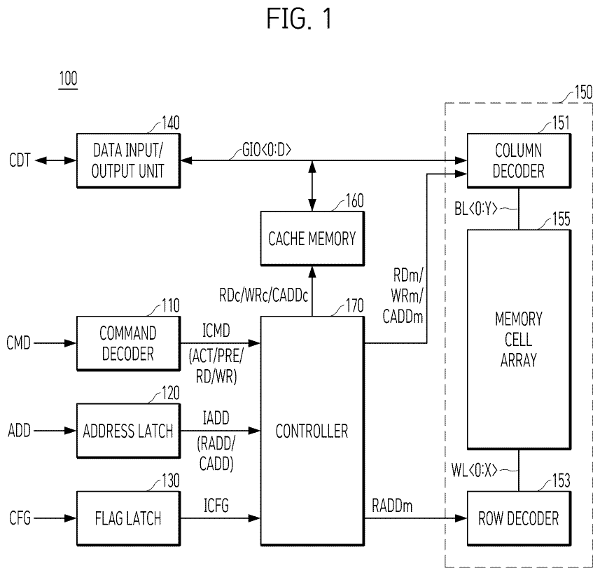

FIG. 1 is a block diagram illustrating a memory device 100 in accordance with an embodiment of the present disclosure.

Referring to FIG. 1, the memory device 100 may include a command decoder 110, an address latch 120, a flag latch 130, a data input and output (input/output) unit 140, a normal memory 150, a cache memory 160, and a controller 170.

The command decoder 110 may generate internal command signals ICMD based on an external command signal CMD. For example, the internal command signals ICMD may include an active signal ACT, a precharge signal PRE, a read command signal RD, and a write command signal WR.

The address latch 120 may generate internal address signals IADD based on an external address signal ADD. For example, the internal address signals IADD may include an internal row address signal RADD and an internal column address signal CADD.

The flag latch 130 may generate an internal flag signal ICFG based on an external flag signal CFG. For example, the internal flag signal ICFG may be activated during a cache load mode.

The data input/output unit 140 may receive data CDT corresponding to external write data and output internal write data to data lines GIO<0:D>. In addition, the data input/output unit 140 may receive internal read data transmitted through the data lines GIO<0:D> and output data CDT corresponding to the internal read data. Hereinafter, the internal read data transmitted through the data lines GIO<0:D> and the internal write data are referred to as “read data” and “write data”, respectively, regardless of modes.

The normal memory 150 may be coupled to the data lines GIO<0:D>. The normal memory 150 may perform a read operation, a write operation or a write-back operation based on a first column command signal RDm or WRm, a first column address signal CADDm and a row address signal RADDm. Hereinafter, the read operation of the normal memory 150 is referred to as a “normal read operation”, and the write operation of the normal memory 150 is referred to as a “normal write operation”.

During the cache load mode, the normal memory 150 may output the read data to the data lines GIO<0:D> through the normal read operation. For example, during the cache load mode, the normal memory 150 may read the read data from one word line corresponding to the row address signal RADDm.

The normal memory 150 may or may not perform the normal read operation or the normal write operation during a cache mode subsequent to the cache load mode.

The normal memory 150 may perform the write-back operation during a precharge mode subsequent to the cache mode. For example, during the cache mode, the write-back operation may be performed only when the cache memory 160 preferentially performs the write operation.

For example, the normal memory 150 may include a column decoder 151, a row decoder 153, and a memory cell array 155. The column decoder 151 may be coupled between the data lines GIO<0:D> and bit lines BL<0:Y>. The column decoder 151 may select one of the bit lines BL<0:Y> based on the first column command signal RDm or WRm and the first column address signal CADDm. The column decoder 151 may transmit normal read data, which is inputted through the selected bit line, as the read data to the data lines GIO<0:D>. The column decoder 151 may transmit the write data, which is inputted through the data lines GIO<0:D>, as normal write data to the selected bit line. The row decoder 153 may be coupled to word lines WL<0:X>. The row decoder 153 may select one of the word lines WL<0:X> based on the row address signal RADDm and activate the selected word line. The memory cell array 155 may be coupled between the bit lines BL<0:Y> and the word lines WL<0:X>. The memory cell array 155 may include memory cells arranged in a two-dimensional or three-dimensional structure. The memory cells may be coupled between the word lines WL<0:X> and the bit lines BL<0:Y>. In some embodiments, the bit lines BL<0:Y> may extend parallel to each other in a column direction, whereas the word lines WL<0:X> may extend parallel to each other in a row direction. Each of the memory cells may be disposed at a different one of intersections between the word lines WL<0:X> and the bit lines BL<0:Y>.

The cache memory 160 may be coupled to the data lines GIO<0:D>. The cache memory 160 may perform the read operation or the write operation based on a second column command signal RDc or WRc and a second column address signal CADDc. Hereinafter, the read operation of the cache memory 160 is referred to as a “cache read operation” and the write operation of the cache memory 160 is referred to as a “cache write operation”.

During the cache load mode, the cache memory 160 may write the read data as load data through the cache write operation. As described above, the read data refers to data read from the normal memory 150 and output to the data lines GIO<0:D> during the cache load mode.

During the cache mode, the cache memory 160 may read the load data as the read data and output the read data to the data lines GIO<0:D> through the cache read operation. During the cache mode, the cache memory 160 may write (i.e., overwrite) the write data as the load data through the cache write operation.

During the precharge mode, the cache memory 160 may read the load data as the write data and output the write data to the data lines GIO<0:D> through the cache read operation.

The controller 170 may generate the first column command signal RDm or WRm, the first column address signal CADDm and the row address signal RADDm for controlling the normal memory 150, and generate the second column command signal RDc or WRc and the second column address signal CADDc for controlling the cache memory 160, based on the internal command signals ICMD, the internal address signals IADD and the internal flag signal ICFG.

During the cache load mode, the controller 170 may generate a first read command signal RDm, the first column address signal CADDm and the row address signal RADDm for controlling the normal read operation of the normal memory 150, and generate a second write command signal WRc and the second column address signal CADDc for controlling the cache write operation of the cache memory 160,. That is, during the cache load mode, the controller 170 may control the normal read operation of the normal memory 150 and the cache write operation of the cache memory 160 so that the normal read data read from the normal memory 150 is written to the cache memory 160 as the load data.

During the cache mode subsequent to the cache load mode, the controller 170 may generate a second read command signal RDc and the second column address signal CADDc instead of the first read command signal RDm and the first column address signal CADDm so that the load data is read as the read data from the cache memory 160 instead of the normal memory 150 when a read command corresponding to a target address is requested,. During the cache mode, the controller 170 may generate the second write command signal WRc and the second column address signal CADDc instead of a first write command signal WRm and the first column address signal CADDm so that the write data is written as the load data to the cache memory 160 instead of the normal memory 150 when a write command corresponding to the target address is requested. That is, during the cache mode, the controller 170 may control the normal memory 150 not to perform the normal read operation or the normal write operation and control the cache memory 160 to perform the cache read operation or the cache write operation when the read command or the write command corresponding to the target address is requested. During the cache mode, the controller 170 may generate the first read command signal RDm and the first column address signal CADDm as default so that the normal read data is read as the read data from the normal memory 150 according to default setting when the read command corresponding to a normal address that is different from the target address is requested. The controller 170 may generate the first write command signal WRm and the first column address signal CADDm so that the write data is written to the normal memory 150 as the normal write data according to the default setting when a write command corresponding to the normal address is requested, during the cache mode. That is, the controller 170 may control the cache memory 160 not to perform the cache read operation or the cache write operation and control the normal memory 150 to perform the normal read operation or the normal write operation when the read command or the write command corresponding to the normal address is requested, during the cache mode.

During the precharge mode subsequent to the cache mode, the controller 170 may generate the second read command signal RDc and the second column address signal CADDc for controlling the cache read operation of the cache memory 160, and generate the first write command signal WRm and the first column address signal CADDm for controlling the normal write operation of the normal memory 150. That is, during the precharge mode, the controller 170 may control the normal memory 150 and the cache memory 160 so that the load data written to the cache memory 160 is written to the normal memory 150 as the write data. This may be the write-back operation.

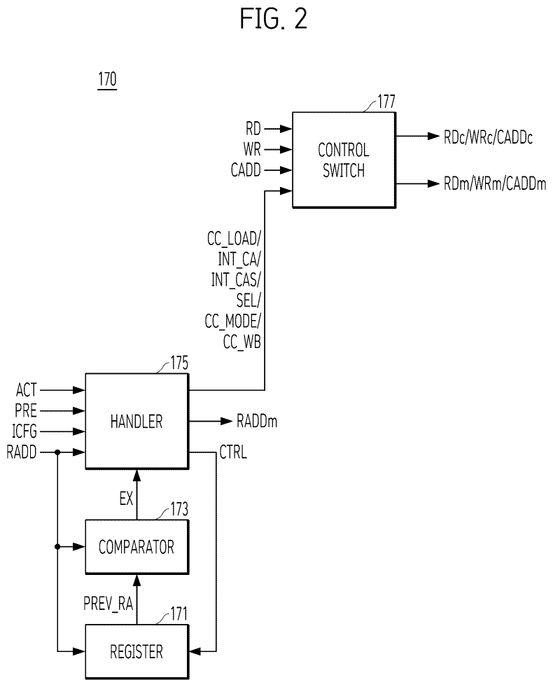

FIG. 2 is a block diagram illustrating the controller 170 illustrated in FIG. 1.

Referring to FIG. 2, the controller 170 may include a register 171, a comparator 173, a handler 175, and a control switch 177.

The register 171 may store the internal row address signal RADD as a previous row address signal PREV_RA based on a control signal CTRL. For example, during the cache load mode, the register 171 may store the internal row address signal RADD as the previous row address signal PREV_RA. The previous row address signal PREV_RA may correspond to the target address.

During the cache mode, the comparator 173 may compare the previous row address signal PREV_RA with the internal row address signal RADD and generate a comparison signal EX corresponding to the comparison result. During the precharge mode, the comparator 173 may compare the previous row address signal PREV_RA with the internal row address signal RADD and generate the comparison signal EX corresponding to the comparison result. During the cache mode or the precharge mode, the comparator 173 may recognize the internal row address signal RADD as a current row address signal and compare the current row address signal with the previous row address signal PREV_RA. For example, when the comparison result indicates that the current row address signal is the same as the previous row address signal PREV_RA, the comparator 173 may activate the comparison signal EX. When the comparison result indicates that the current row address is different from the previous row address signal PREV_RA, the comparator 173 may deactivate the comparison signal EX.

The handler 175 may generate a load control signal CC_LOAD, a self-strobe signal INT_CAS, a self-column address signal INT_CA, a cache selection signal SEL, a cache mode signal CC_MODE, a write-back control signal CC_WB, the row address signal RADDm and the control signal CTRL based on the active signal ACT, the precharge signal PRE, the internal flag signal ICFG, the internal row address signal RADD (i.e., the current row address signal) and the comparison signal EX.

For example, during the cache load mode, the handler 175 may activate the control signal CTRL, the load control signal CC_LOAD and the cache mode signal CC_MODE based on the active signal ACT and the internal flag signal ICFG. The control signal CTRL may be activated during an initial period of the cache load mode. The load control signal CC_LOAD may be activated during the initial period and a middle period of the cache load mode. The cache mode signal CC_MODE may be activated during a last period of the cache load mode. During the cache load mode, the handler 175 may generate the self-strobe signal INT_CAS and the self-column address signal INT_CA based on the load control signal CC_LOAD. During the cache mode, the handler 175 may continuously activate the cache mode signal CC_MODE and determine whether to activate the cache selection signal SEL based on the comparison signal EX. For example, the handler 175 may activate the cache selection signal SEL based on the activated comparison signal EX and deactivate the cache selection signal SEL based on the deactivated comparison signal EX. During the precharge mode, the handler 175 may activate the write-back control signal CC_WB based on the precharge signal PRE. For example, during the precharge mode, the handler 175 may activate the write-back control signal CC_WB only when the write operation of the cache memory 160 is preferentially performed during the cache mode. During the precharge mode, the handler 175 may generate the self-strobe signal INT_CAS and the self-column address signal INT_CA based on the write-back control signal CC_WB.

The control switch 177 may generate the first column command signal RDm or WRm and the first column address signal CADDm for controlling the normal memory 150 or the second column command signal RDc or WRc and the second column address signal CADDc for controlling the cache memory 160, based on the read command signal RD, the write command signal WR, the internal column address signal CADD and the output signals of the handler 175 such as CC_LOAD, INT_CAS, INT_CA, SEL, CC_MODE and CC_WB.

For example, the control switch 177 may generate the first column command signal RDm or WRm and the first column address signal CADDm and then generate the second column command signal RDc or WRc and the second column address signal CADDc, based on the self-strobe signal INT_CAS and the self-column address signal INT_CA during the cache load mode, that is, when the load control signal CC_LOAD is activated. The control switch 177 may generate the first column command signal RDm or WRm and the first column address signal CADDm, or the second column command signal RDc or WRc and the second column address signal CADDc, based on the read command signal RD, the write command signal WR, the internal column address signal CADD and the cache selection signal SEL during the cache mode, that is, when the cache mode signal CC_MODE is activated. The control switch 177 may generate the second column command signal RDc or WRc and the second column address signal CADDc and then generate the first column command signal RDm or WRm and the first column address signal CADDm, based on the self-strobe signal INT_CAS and the self-column address signal INT_CA during the precharge mode, that is, when the write-back control signal CC_WB is activated.

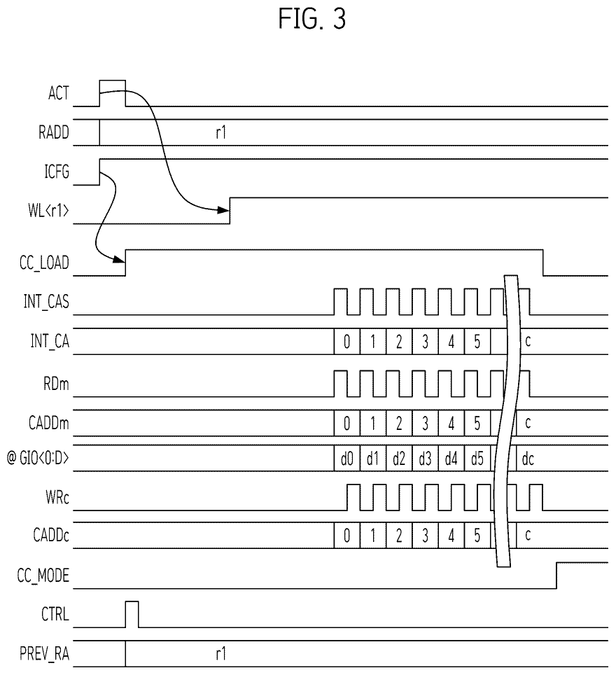

Hereinafter, an operation of the memory device 100, which has the above-described configuration illustrated in FIGS. 1 and 2, is described with reference to FIGS. 3 to 6.

FIG. 3 is a timing diagram of the operation of the memory device 100 illustrated in FIG. 1 according to the cache load mode.

Referring to FIG. 3, when the active signal ACT is activated and the internal row address signal RADD is inputted, the internal flag signal ICFG may be activated. The internal flag signal ICFG may be generated from an external device, for example, a host.

The normal memory 150 may activate a word line WL<r1>, which corresponds to the internal row address signal RADD among the word lines WL<0:X>, based on the row address signal RADDm. The controller 170 may internally generate the self-strobe signal INT_CAS and the internal address signal INT_CA based on the internal flag signal ICFG, and generate the first read command signal RDm and the first column address signal CADDm based on the self-strobe signal INT_CAS and the internal address signal INT_CA. Then, the controller 170 may generate the second write command signal WRc and the second column address signal CADDc.

The normal memory 150 may perform the normal read operation based on the first read command signal RDm and the first column address signal CADDm. The cache memory 160 may perform the cache write operation based on the second write command signal WRc and the second column address signal CADDc. For example, when the normal memory 150 sequentially reads the normal read data according to the first column address signal CADDm and provides the data lines GIO<0:D> with the normal read data as read data d0 to dc, the cache memory 160 may sequentially write the read data d0 to dc as the load data according to the second column address signal CADDc.

The controller 170 may store the internal row address signal RADD, which is inputted during the cache load mode, as the previous row address signal PREV_RA.

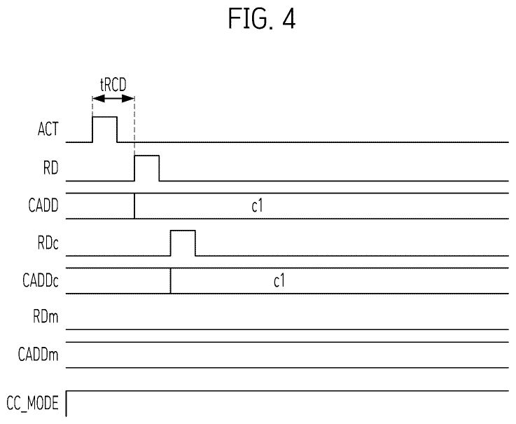

FIG. 4 is a timing diagram of the read operation of the memory device 100 illustrated in FIG. 1 according to the cache mode.

Referring to FIG. 4, the controller 170 may compare the internal row address signal RADD, which is inputted along with the active signal ACT, with the previous row address signal PREV_RA.

When the internal row address signal RADD (i.e., a current row address signal) that is inputted is the same as the previous row address signal PREV_RA, the controller 170 may access the cache memory 160 instead of the normal memory 150. For example, the controller 170 may generate the second read command signal RDc and the second column address signal CADDc instead of the first read command signal RDm and the first column address signal CADDm. The cache memory 160 may provide the data lines GIO<0:D> with the load data as the read data based on the second read command signal RDc and the second column address signal CADDc. That is, when the internal row address signal RADD that is inputted is the same as the previous row address signal PREV_RA, the controller 170 may control the normal memory 150 and the cache memory 160 so that the cache read operation is performed.

When the internal row address signal RADD that is inputted is different from the previous row address signal PREV_RA, the controller 170 may access the normal memory 150 according to the default setting. For example, the controller 170 may generate the first read command signal RDm and the first column address signal CADDm as default. The normal memory 150 may provide the data line GIO<0:D> with the normal read data as the read data based on the first read command signal RDm and the first column address signal CADDm. That is, when the internal row address signal RADD that is inputted is different from the previous row address signal PREV_RA, the controller 170 may control the normal memory 150 and the cache memory 160 so that the normal read operation is performed.

As described above, according to an embodiment of the present disclosure, access time, e.g., tRCD, may be significantly reduced when the controller 170 accesses the cache memory 160 instead of the normal memory 150 compared to when the controller 170 accesses the normal memory 150, during the read operation according to the cache mode.

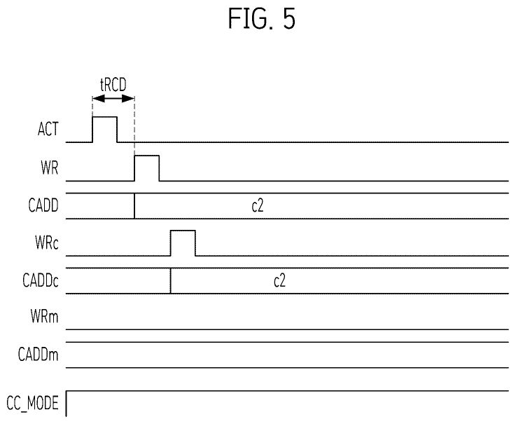

FIG. 5 is a timing diagram of the write operation of the memory device 100 illustrated in FIG. 1 according to the cache mode.

Referring to FIG. 5, the controller 170 may compare the internal row address signal RADD, which is inputted along with the active signal ACT, with the previous row address signal PREV_RA.

When the internal row address signal RADD that is inputted is the same as the previous row address signal PREV_RA, the controller 170 may access the cache memory 160 instead of the normal memory 150. For example, the controller 170 may generate the second write command signal WRc and the second column address signal CADDc instead of the first write command signal WRm and the first column address signal CADDm. The second column address signal CADDc generated during the write operation may be the same as or different from the second column address signal CADDc generated during the read operation (that is, c1=c2 or c1≠c2). The cache memory 160 may write, i.e., overwrite, the write data, which is provided through the data line GIO<0:D>, as the load data based on the second write command signal WRc and the second column address signal CADDc. That is, when the internal row address signal RADD that is inputted is the same as the previous row address signal PREV_RA, the controller 170 may control the normal memory 150 and the cache memory 160 so that the cache write operation is performed.

When the internal row address signal RADD that is inputted is different from the previous row address signal PREV_RA, the controller 170 may access the normal memory 150 according to the default setting. For example, the controller 170 may generate the first write command signal WRm and the first column address signal CADDm as default. The normal memory 150 may write the write data, which is provided through the data lines GIO<0:D>, as the normal write data based on the first write command signal WRm and the first column address signal CADDm. That is, when the internal row address signal RADD that is inputted is different from the previous row address signal PREV_RA, the controller 170 may control the normal memory 150 and the cache memory 160 so that the normal write operation is performed.

As described above, according to an embodiment of the present disclosure, access time, e.g., tRCD, may be significantly reduced when the controller 170 accesses the cache memory 160 instead of the normal memory 150 compared to when the controller 170 accesses the normal memory 150, during the write operation according to the cache mode.

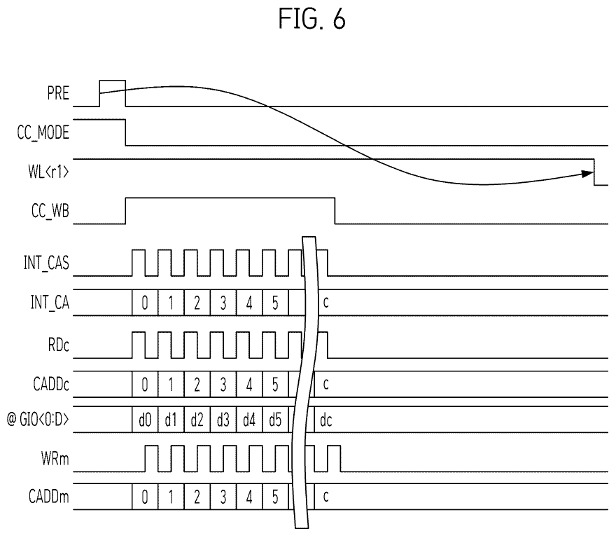

FIG. 6 is a timing diagram of the write-back operation of the memory device 100 illustrated in FIG. 1 according to the precharge mode. For example, the write-back operation may be performed only when the cache write operation described in FIG. 5 is preferentially performed.

Referring to FIG. 6, the controller 170 may activate the write-back control signal CC_WB based on the precharge signal PRE. The controller 170 may internally generate the self-strobe signal INT_CAS and the internal address signal INT_CA based on the write-back control signal CC_WB. The controller 170 may generate the second read command signal RDc and the second column address signal CADDc based on the self-strobe signal INT_CAS and the internal address signal INT_CA, and then generate the first write command signal WRm and the first column address signal CADDm.

The cache memory 160 may perform the cache read operation based on the second read command signal RDc and the second column address signal CADDc. The normal memory 150 may perform the normal write operation based on the first write command signal WRm and the first column address signal CADDm. For example, when the cache memory 160 sequentially provides the data lines GIO<0:D> with the load data as read data d0 to dc according to the second column address CADDm, the normal memory 150 may sequentially write the read data d0 to dc as the normal write data according to the first column address signal CADDm.

When the read data d0 to dc read from the cache memory 160 is written to the normal memory 150, the controller 170 may deactivate the word line WL<r1> corresponding to the internal row address signal RADD, and therefore the precharge operation may terminate.

According to an embodiment of the present disclosure, because the command signal RD or WR is inputted immediately after the active signal ACT is inputted during the cache mode, the time, i.e., tRCD, between the active signal ACT and the command signal RD or WR may be minimized.

According to an embodiment of the present disclosure, a cache memory may be included in a memory device, which makes it possible to reduce access time, i.e., tRCD, during a read operation or a write operation.

While the present invention has been illustrated and described with respect to specific embodiments, the disclosed embodiments are provided for the description, and not intended to be restrictive. Further, it is noted that the embodiments of the present disclosure may be achieved in various ways through substitution, change, and modification that fall within the scope of the following claims, as those skilled in the art will recognize in light of the present disclosure. The embodiments may be combined to form additional embodiments.

What is claimed is:

1. A memory device comprising:
a normal memory configured to perform a normal read operation or a normal write operation based on a first command signal, a first column address signal and a row address signal;
a cache memory configured to perform a cache read operation or a cache write operation based on a second command signal and a second column address signal;
a comparator configured to compare a previous row address signal with a current row address signal and generate a comparison signal corresponding to the comparison result;
a handler configured to generate a load control signal, a self-strobe signal, a self-column address signal and the row address signal based on an active signal, a flag signal, the current row address signal and the comparison signal; and
a control switch configured to generate the first command signal, the first column address signal, the second command signal and the second column address signal based on the load control signal, the self-strobe signal and the self-column address signal.

2. The memory device of claim 1, wherein:
when the load control signal is activated, the control switch generates the first command signal and the first column address signal and then generates the second command signal and the second column address signal,
the normal memory performs the normal read operation based on the first command signal and the first column address signal, and
the cache memory performs the cache write operation based on the second command signal and the second column address signal.

3. The memory device of claim 1, wherein, during a cache mode,
the handler generates a cache mode signal and a selection signal, and
wherein the control switch generates the first command signal and the first column address signal or the second command signal and the second column address signal based on the cache mode signal and the selection signal.

4. The memory device of claim 3, wherein the handler activates the cache mode signal after deactivating the load control signal and determines whether to activate the selection signal based on the comparison signal, and
wherein the control switch generates the second command signal and the second column address signal when the selection signal is activated.

5. The memory device of claim 1, wherein:
the handler generates a write-back control signal during a precharge mode,
when the write-back control signal is activated, the control switch generates the second command signal and the second column address signal and then generates the first command signal and the first column address signal,
the cache memory performs the cache read operation based on the second command signal and the second column address signal, and
the normal memory performs the normal write operation based on the first command signal and the first column address signal.

6. The memory device of claim 1, further comprising a register configured to store the previous row address signal based on a control signal,
wherein the handler generates the control signal based on the flag signal.

7. A memory device comprising:
at least one data line;
a normal memory coupled to the data line and configured to output read data to the data line through a normal read operation during a cache load mode;
a cache memory coupled to the data line and configured to write the read data as load data through a cache write operation during the cache load mode; and
a controller configured to control the normal read operation of the normal memory and the cache write operation of the cache memory by generating and using a self-strobe signal and a self-column address signal during the cache load mode.

8. The memory device of claim 7, wherein the controller controls the cache memory so that the load data is read from the cache memory according to a row address signal when a read command of the read data is requested, during a cache mode subsequent to the cache load mode.

9. The memory device of claim 7, wherein the controller controls the cache memory so that the write data is written to the cache memory when a write command of the write data is requested, during a cache mode subsequent to the cache load mode.

10. The memory device of claim 9, wherein the controller controls the cache memory and the normal memory so that the write data is written to the normal memory, during a precharge mode subsequent to the cache mode.

11. The memory device of claim 7, wherein the controller includes:
a comparator configured to compare a previous row address signal with a current row address signal and generate a comparison signal corresponding to the comparison result;
a handler configured to generate a load control signal, the self-strobe signal, the self-column address signal and a row address signal based on an active signal, a flag signal, the current row address signal and the comparison signal; and
a control switch configured to generate a first command signal, a first column address signal, a second command signal and a second column address signal based on the load control signal, the self-strobe signal and the self-column address signal.

12. The memory device of claim 11, wherein:
the control switch generates the first command signal and the first column address signal when the load control signal is activated and then generates the second command signal and the second column address signal,
the normal memory performs the normal read operation based on the row address signal, the first command signal and the first column address signal, and
the cache memory performs the cache write operation based on the second command signal and the second column address signal.

13. The memory device of claim 11, wherein,
during a cache mode subsequent to the cache load mode,
the handler generates a cache mode signal and a selection signal, and
wherein the control switch generates the first command signal and the first column address signal or the second command signal and the second column address signal based on the cache mode signal and the selection signal.

14. The memory device of claim 13, wherein the handler activates the cache mode signal after deactivating the load control signal and determines whether to activate the selection signal based on the comparison signal, and
wherein the control switch generates the second command signal and the second column address signal when the selection signal is activated.

15. The memory device of claim 13, wherein:
the handler generates a write-back control signal during a precharge mode subsequent to the cache mode,
the control switch generates the second command signal and the second column address signal when the write-back control signal is activated and then generates the first command signal and the first column address signal,
the cache memory performs a cache read operation based on the second command signal and the second column address signal, and
the normal memory performs a normal write operation based on the first command signal and the first column address signal.

16. The memory device of claim 11, wherein the controller further includes a register configured to store the previous row address signal based on a control signal, and
wherein the handler generates the control signal based on the flag signal.

17. A memory device comprising:
a memory cell array;
a cache memory; and
a controller configured to:
perform a normal read operation or a normal write operation on the memory cell array based on a first command signal, a first column address signal and a row address signal,
perform a cache read operation or a cache write operation on the cache memory based on a second command signal and a second column address signal,
during a cache mode, generate the first command signal and the first column address signal or the second command signal and the second column address signal, and
during a precharge mode, generate the second command signal and the second column address signal, and then generate the first command signal and the first column address signal.
